(19) United States
(12) Patent Application Publication
(10) Pub. No.: US 2016/0049502 A1
(43) Pub. Date: Feb. 18, 2016

(54) HETEROJUNCTION BIPOLAR TRANSISTOR WITH BLOCKING LAYER STRUCTURE

(71) Applicant: VISUAL PHOTONICS EPITAXY CO., LTD., Taoyuan (TW)

(72) Inventors: Yu-Chung Chin, New Taipei City (TW); Chao-Hsing Huang, Taipei City (TW); Hung-Chi Hsiao, Changhua County (TW)

(21) Appl. No.: 14/712,968

(22) Filed: May 15, 2015

Related U.S. Application Data
(60) Provisional application No. 62/037,765, filed on Aug. 15, 2014.

(51) Int. Cl. H01L 29/737; H01L 29/207; H01L 27/06; H01L 29/08; H01L 29/10; H01L 29/778; H01L 29/205; H01L 29/15

(52) U.S. Cl. CPC H01L 29/7371; H01L 29/205; H01L 29/207; H01L 29/155; H01L 29/0804; H01L 29/0821; H01L 29/1004; H01L 29/778; H01L 27/0623

(57) ABSTRACT

Provided is a heterojunction bipolar transistor (HBT), including a GaAs substrate; a subcollector layer stacked on the GaAs substrate, wherein a part of or all of the subcollector layer is formed by N-type group III-V semiconductors doped by at least Te and/or Se; a blocking layer structure directly or indirectly stacked on the subcollector layer, and formed by N-type group III-V semiconductors doped by at least group IV elements, a collector layer stacked on the blocking layer structure, and formed by N-type group III-V semiconductors; a base layer stacked on the collector layer, and formed by P-type group III-V semiconductors; an emitter layer stacked on the base layer and formed by N-type group III-V semiconductors; an emitter cap layer stacked on the emitter layer and formed by N-type group III-V semiconductors; and an ohmic contact layer stacked on the emitter cap layer and formed by N-type group III-V semiconductors.

### CROSS-REFERENCES TO RELATED APPLICATION

This application claims the priority of U.S. provisional patent application No. 62/037,765, filed on Aug. 15, 2014, which is incorporated herewith by reference.

### BACKGROUND OF THE INVENTION

1. Field of the Invention

The present invention relates generally to a HBT (heterojunction bipolar transistor), and more particularly, to a HBT with a blocking layer structure directly or indirectly formed on a subcollector layer composed of a N-type semiconductor doped by at least Te and/or Se, and to the blocking layer structure composed of group III-V semiconductors doped by at least group IV elements.

2. The Prior Arts

A HBT is a type of BJT (bipolar junction transistor). A heterojunction interface is formed by means of the emitter region and the base region of dissimilar semiconductor materials to enable a HBT to have better high-frequency characteristic, up to hundred GHz, as compared to a general BJT. Accordingly, it is commonly used in modern ultra-fast circuits, radio-frequency (RF) systems and mobile phones.

In order to improve the electrical characteristic of the HBT, the parasitic effect of the HBT may be reduced. For example, knee voltage can be reduced by reducing the parasitic resistance of the emitter and collector of a HBT. According to the prior art, by means of increasing the subcollector layer carrier concentration the subcollector sheet resistance and the collector ohmic contact resistance can be reduced, such that the HBT knee voltage can be reduced.

In general, a HBT includes a subcollector layer, a collector layer, a base layer, an emitter layer, an emitter cap layer and an ohmic contact layer which are sequentially formed on a substrate from bottom to top, wherein the subcollector layer is formed by highly doped Si, but the Si-doped subcollector layer with the highest activated carrier concentration is about 6×10¹⁸ cm⁻³, such that reduction of the collector parasitic resistance and the collector ohmic contact resistance of a HBT may be limited. In addition, under high temperature, heavily Si-doped subcollector layer may induce the carrier de-activation effect, such that the activated carrier concentration is reduced. Accordingly, the collector parasitic resistance and the collector ohmic contact resistance are increased, and the electrical characteristic of the HBT is deteriorated. However, the subcollector layer doped by Te and/or Se may avoid the aforesaid problems. The carrier concentration of the subcollector layer doped with Te and/or Se can be greater than 2×10¹⁹cm⁻³, such that collector parasitic resistance and collector ohmic contact resistance are effectively reduced in order to improve the electrical characteristic of the HBT. Furthermore, Te or Se has low diffusivity and low de-activation rate characteristics after high temperature thermal cycle stress. Therefore, the subcollector layer doped with Te and/or Se may maintain high activated carrier concentration after the high temperature thermal cycle stress, and electrical characteristic of the HBT may not be deteriorated.

However, as for the subcollector layer of a HBT in the prior art, the heavily Te or Se-doped subcollector layer may create various defects such as Ga vacancies (V_{Ga}) and their related compounds (Ga vacancy-Te donor complex; V_{Ga}-Te_{As}). Those defects can diffuse to the layers formed on the subcollector layer. Accordingly, the current gain of the HBT may be reduced, and/or a depletion region in the collector layer above the subcollector layer may also be formed. Therefore, carrier depletion may increase collector resistance and interface resistance of the collector layer and the subcollector layer, such that additional parasitic resistance of the collector of the HBT may be formed. Since the base-collector CV profile of the original designed may be changed, the base-collector CV profile will become un-predictable, and the, difficulty of the circuit design will be increased.

Therefore, the HBT device and circuit performance can be improved. It is necessary to have a HBT with a blocking layer structure directly or indirectly formed on a subcollector layer whereby a part of or all of the subcollector layer is formed by N-type group III-V semiconductors doped by at least Te and/or Se to reduce the collector resistance and knee voltage and to avoid the depletion of the collector layer and/or the decrease of current gain.

### SUMMARY OF THE INVENTION

In view of the drawbacks of the prior art, the primary objective of the present invention is to provide a heterojunction bipolar transistor (HBT) including a substrate formed by GaAs; a subcollector layer stacked on the substrate, wherein a part of or all of the subcollector layer may be formed by N-type group III-V semiconductors doped by at least Te and/or Se; a blocking layer structure directly or indirectly stacked on the subcollector layer, and formed by N-type group III-V semiconductors doped by at least group IV elements, a collector layer stacked on the blocking layer structure, and formed by N-type group III-V semiconductors; a base layer stacked on the collector layer, and formed by P-type group III-V semiconductors; an emitter layer stacked on the base layer, and formed by N-type group III-V semiconductors that are different from those of the base layer; an emitter cap layer stacked on the emitter layer, and formed by N-type group III-V semiconductors; and an ohmic contact layer stacked on the emitter cap layer, and formed by N-type group III-V semiconductors.

Preferably, the blocking layer structure may be stacked directly on the subcollector layer.

Preferably, the blocking layer structure may be formed by a single blocking layer or a plurality of blocking layers.

According to the present invention, the blocking layer structure may include a total group IV elements dosage, that is, a thickness T of a blocking layer or the sum of thicknesses T of blocking layers that is multiplied by a group IV elements dosage concentration D of the blocking layer(s) is greater than or equal to 1×10¹² cm⁻² (i.e., ΣT×D≧1×10¹² cm⁻²).

Preferably, the blocking layer structure of the present invention may include a total group IV elements dosage, that is, a thickness T of a blocking layer or the sum of thicknesses T of blocking layers that is multiplied by a group IV elements dosage concentration D of the blocking layer(s) is greater than or equal to 1×10¹³ cm ⁻² (i.e., ΣT×D≧1×10¹³ cm⁻²).

Most preferably, the blocking layer structure of the present invention may include a total group IV elements dosage, that is, a thickness T of a blocking layer or the sum of thicknesses T of blocking layers that is multiplied by a group IV elements dosage concentration D of the blocking layer(s) is greater than or equal to 1×10¹⁴ cm⁻² (i.e., ΣT×D≧1×10¹⁴ cm⁻²).

Preferably, at least one layer of the blocking layer structure may include the group IV elements dosage concentration greater than or equal to 1×10¹⁸ cm⁻³.

Preferably, the blocking layer structure may be formed by at least one of GaAs, AlGaAs, InGaAs, InGaP, InGaAsP, GaAsSb, InGaAsN, AlAs, AlGaInP and a combination thereof and/or a superlattice structure.

Most preferably, the blocking layer structure may be formed by at least one of GaAs, InGaAs, GaAsSb, InGaAsN, InGaAsP, InGaP and a combination thereof and/or a superlattice structure.

Preferably, the group IV elements dosage of the blocking layer structure may be formed by at least one of Si, Ge and Sn.

Most preferably, the group IV elements dosage of the blocking layer structure may be formed by Si.

Preferably, the blocking layer structure may be formed based on MOCVD technology, and the materials for growing the blocking layer structure may include group III including at least one of TMAl, TEAl, TMIn, TEIn, TIPIn, TMGa, TEGa, TIPGa, TIBGa and TTBGa, and group V including at least one of PH₃, TBP, AsH₃, DMAs, TMAs, TEAs, DEAs, TBAs, TESb, TMSb, DMHy, MMHy and NH₃.

Most preferably, the blocking layer structure may be formed based on MOCVD technology, and the materials for growing the blocking layer structure may include group III including at least one of TMIn, TMGa, TEGa, and group V including at least one of PH₃, TBP, AsH₃, TESb, NH₃ and TBAs,

Preferably, the collector layer may be formed by at least one of N-type GaAs, AlGaAs, InGaAs, InGaP and InGaAsP. The base layer may be formed by at least one of P-type GaAs, InGaAs, InGaAsN and GaAsSb. The emitter layer may be formed by at least one of N-type AlGaInP, InGaP, InGaAsP and AlGaAs. The emitter cap may be formed by at least one of N-type GaAs, InGaP, InGaAsP and AlGaAs. In addition, the ohmic contact layer may be formed by at least one of N-type GaAs and InGaAs.

Furthermore, according to another embodiment of the present invention, the present invention further provides a HBT includes a substrate formed by GaAs; a transistor directly or indirectly stacked on the substrate; a subcollector layer stacked on the transistor, wherein a part of or all of the subcollector layer may be formed by N-type group III-V semiconductors doped by at least Te and/or Se; a blocking layer structure directly or indirectly stacked on the subcollector layer, and formed by N-type group III-V semiconductors doped by at least group IV elements, a collector layer stacked on the blocking layer structure, and formed by N-type group III-V semiconductors; a base layer stacked on the collector layer, and formed by P-type group III-V semiconductors; an emitter layer stacked on the base layer, and formed by N-type group III-V semiconductors that are different from those of the base layer; an emitter cap layer stacked on the emitter layer, and formed by N-type group III-V semiconductors; and an ohmic contact layer stacked on the emitter cap layer, and formed by N-type group III-V semiconductors.

According to the present invention, the transistor may be a FET, and, preferably, the transistor may be a pHEMT (Pseudomorphic High Electron Mobility Transistor).

Preferably, the blocking layer structure may be stacked directly on the subcollector layer.

Preferably, the blocking layer structure may be formed by a single blocking layer or a plurality of blocking layers.

According to the present invention, the blocking layer structure may include a total group IV elements dosage, that is, a thickness T of a blocking layer or the sum of thicknesses T of blocking layers that is multiplied by a group IV elements dosage concentration D of the blocking layer(s) is greater than or equal to 1×10¹² cm ⁻² (i.e., ΣT×D≧1×10¹² cm⁻²).

Preferably, the blocking layer structure of the present invention may include a total group IV elements dosage, that is, a thickness T of a blocking layer or the sum of thicknesses T of blocking layers that is multiplied by a group IV elements dosage concentration D of the blocking layer(s) is greater than or equal to 1×10¹³ cm⁻² (i.e., ΣT×D≧1×10¹³ cm⁻²).

Most preferably, the blocking layer structure of the present invention may include a total group IV elements dosage, that is, a thickness T of a blocking layer or the sum of thicknesses T of blocking layers that is multiplied by a group IV elements dosage concentration D of the blocking layer(s) is greater than or equal to 1×10¹⁴ cm⁻² (i.e., ΣT×D≧1×10¹⁴ cm⁻²).

Preferably, at least one layer of the blocking layer structure may include the group IV elements dosage concentration greater than or equal to 1×10¹⁸ cm⁻³.

Preferably, the blocking layer structure may be formed by at least one of GaAs, AlGaAs, InGaAs, InGaP, InGaAsP, GaAsSb, InGaAsN, AlAs, AlGaInP and a combination thereof and/or a superlattice structure.

Most preferably, the blocking layer structure may be formed by at least one of GaAs, InGaAs, GaAsSb, InGaAsN, InGaAsP, InGaP and a combination thereof and/or a superlattice structure.

Preferably, the group IV elements dosage of the blocking layer structure may be formed by at least one of Si, Ge and Sn.

Most preferably, the group IV elements dosage of the blocking layer structure may be formed by Si.

Preferably, the blocking layer structure may be formed based on MOCVD technology, and the materials for growing the blocking layer structure may include group III including at least one of TMAl, TEAl, TMIn, TEIn, TIPIn, TMGa, TEGa, TIPGa, TIBGa and TTBGa and group V including at least one of PH₃, TBP, AsH₃, DMAs, TMAs, TEAs, DEAs, TBAs, TESb, TMSb, DMHy, MMHy and NH₃.

Most preferably, the blocking layer structure may be formed based on MOCVD technology, and the materials for growing the blocking layer structure may include group III including at least one of TMIn, TMGa, TEGa, and group V including at least one of PH₃, TBP, AsH₃, TESb, NH₃ and TBAs.

Preferably, the collector layer may be formed by at least one of N-type GaAs, AlGaAs, InGaAs, InGaP and InGaAsP. The base layer may be formed by at least one of P-type GaAs, InGaAs, InGaAsN and GaAsSb. The emitter layer may be formed by at least one of N-type AlGaInP, InGaP, InGaAsP and AlGaAs. The emitter cap layer may be formed by at least one of N-type GaAs, InGaP, InGaAsP and AlGaAs. The ohmic contact layer may be formed by at least one of N-type GaAs and InGaAs.

Preferably, the pHEMT may include at least one buffer layer, a first donor layer, a first spacer layer, a channel layer, a second spacer layer, a second donor layer, a Schottky layer, an etch stop layer, and a cap layer for an ohmic contact that are sequentially formed on the substrate from bottom to top.

Preferably, the at least one buffer layer may be formed by group III-V semiconductors.

Preferably, the first donor layer and the second donor layer may be formed by at least one of N-type GaAs, N-type AlGaAs, N-type InAlGaP, N-type InGaP, and N-type InGaAsP.

Preferably, the first spacer layer and the second spacer layer may be formed by at least one of GaAs, AlGaAs, InAlGaP, InGaP and InGaAsP.

Preferably, the channel layer may be formed by at least one of GaAs, InGaAs, AlGaAs, InAlGaP, InGaP and InGaAsP.

Preferably, the Schottky layer may be formed by at least one of GaAs, AlGaAs, InAlGaP, InGaP and InGaAsP.

Preferably, the etch stop layer may be formed by at least one of GaAs, AlGaAs, InAlGaP, InGaAsP, InGaP and AlAs.

Preferably, the cap layer may be formed by N-type group III-V semiconductors.

### BRIEF DESCRIPTION OF THE DRAWINGS

The present invention will be apparent to those skilled in the art by reading the following detailed description of a preferred embodiment thereof, with reference to the attached drawings, in which:

FIG. 1 is a sectional view illustrating a HBT according to a first preferred embodiment of the present invention;

FIG. 2 is a sectional view illustrating a HBT according to a second preferred embodiment of the present invention;

FIG. 3 is a sectional view illustrating a HBT according to a third preferred embodiment of the present invention; and

FIG. 4 is a sectional view illustrating a HBT according to a fourth preferred embodiment of the present invention.

### DETAILED DESCRIPTION OF THE PREFERRED EMBODIMENT

The accompanying drawings are included to provide a further understanding of the invention, and are incorporated in and constitute a part of this specification. The drawings illustrate embodiments of the invention and, together with the description, serve to explain the principles of the invention.

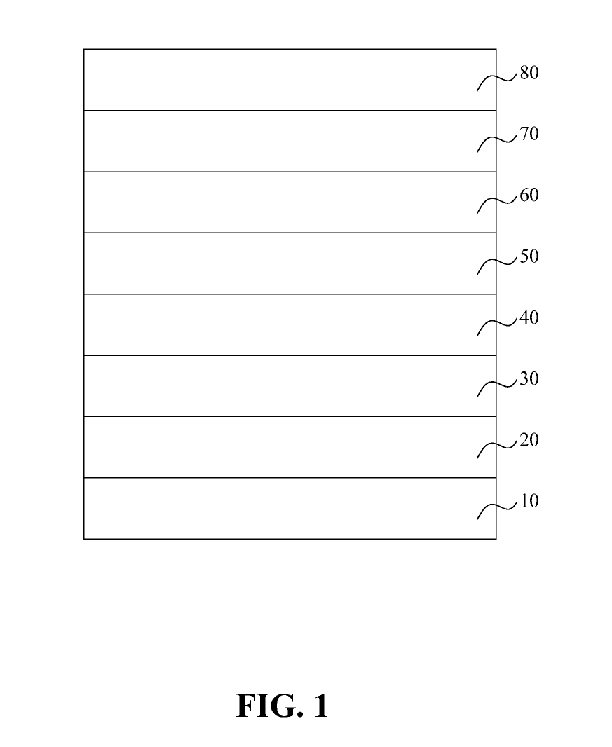

With regard to FIGS. 1-4, the drawings showing embodiments are semi-diagrammatic and not to scale and, particularly, some of the dimensions are for clarity of presentation and are shown exaggerated in the drawings. Similarly, although the views in the drawings for ease of description generally show similar orientations, this depiction in the drawings is arbitrary for the most part. Generally, the present invention can be operated in any orientation.

In order to solve the aforesaid problems, a HBT of the present invention includes a substrate formed by GaAs; a subcollector layer stacked on the substrate, wherein a part of or all of the subcollector layer may be formed by N-type group III-V semiconductors doped by at least Te and/or Se; a blocking layer structure directly or indirectly stacked on the subcollector layer, and formed by N-type group III-V semiconductors doped by at least group IV elements, a collector layer stacked on the blocking layer structure, and formed by N-type group III-V semiconductors; a base layer stacked on the collector layer, and formed by P-type group III-V semiconductors; an emitter layer stacked on the base layer, and formed by N-type group III-V semiconductors that are different from those of the base layer; an emitter cap layer stacked on the emitter layer, and formed by N-type group III-V semiconductors; and an ohmic contact layer stacked on the emitter cap layer, and formed by N-type group III-V semiconductors.

Furthermore, according to the present invention, a transistor (for example, a FET) may be directly or indirectly formed on a GaAs substrate. A subcollector layer may be formed on the transistor, and a part of or all of the subcollector layer may be formed by N-type group III-V semiconductor doped by at least Te and/or Se. A blocking layer structure may be directly or indirectly formed on the subcollector layer and may be formed by N-type group III-V semiconductors doped by at least group IV elements. A collector layer may be stacked on the blocking layer structure, and may be formed by N-type group III-V semiconductors; a base layer may be stacked on the collector layer, and may be formed by P-type group III-V semiconductors; and an emitter layer may be stacked on the base layer, and may be formed by N-type group III-V semiconductors that are different from those of the base layer. An emitter cap layer may be stacked on the emitter layer, and may be formed by N-type group III-V semiconductors; and an ohmic contact layer may be stacked on the emitter cap layer, and may be formed by N-type group III-V semiconductors.

The blocking layer structure of the present invention may be stacked directly on the subcollector layer.

The blocking layer structure of the present invention may be formed by a single blocking layer or a plurality of blocking layers.

According to the present invention, the blocking layer structure may include a total group IV elements dosage, that is, a thickness T of a blocking layer or the sum of thicknesses T of blocking layers that is multiplied by a group IV elements dosage concentration D of the blocking layer(s) is greater than or equal to 1×10¹² cm⁻² (i.e., ΣT×D≧1×10¹² cm⁻²).

Preferably, the blocking layer structure of the present invention may include a total group IV elements dosage, that is, a thickness T of a blocking layer or the sum of thicknesses T of blocking layers that is multiplied by a group IV elements dosage concentration D of the blocking layer(s) is greater than or equal to 1×10¹³ cm ⁻² (i.e., ΣT×D≧1×10¹³ cm⁻²).

Most preferably, the blocking layer structure of the present invention may include a total group IV elements dosage, that is, a thickness T of a blocking layer or the sum of thicknesses T of blocking layers that is multiplied by a group IV elements dosage concentration D of the blocking layer(s) is greater than or equal to 1×10¹⁴ cm⁻² (i.e., ΣT×D≧1×10¹⁴ cm⁻²).

Preferably, at least one layer of the blocking layer structure may include the group IV elements dosage concentration greater than or equal to 1×10¹⁸ cm⁻³.

According to the present invention, the blocking layer structure may be formed by at least one of GaAs, AlGaAs, InGaAs, InGaP, InGaAsP, GaAsSb, InGaAsN, AlAs and AlGaInP, or by a combination of the aforesaid material(s) and/or a superlattice structure.

According to the preferred embodiment of the present invention, the blocking layer structure may be formed by at least one of GaAs, InGaAs, GaAsSb, InGaAsN, InGaAsP, InGaP and a combination thereof and/or a superlattice structure.

According to the present invention, the group IV elements dosage of the blocking layer structure may be formed by at least one of Si, Ge and Sn.

According to the preferred embodiment of the present invention, the group IV elements dosage of the blocking layer structure may be formed by Si.

According to the present invention, the blocking layer structure may be formed based on MOCVD technology, and the materials for growing the blocking layer structure may include group III including at least one of TMAl, TEAl, TMIn, TEIn, TIPIn, TMGa, TEGa, TIPGa, TIBGa and TTBGa and group V including at least one of PH₃, TBP, AsH₃, DMAs, TMAs, TEAs, DEAs, TBAs, TESb, TMSb, DMHy, MMHy and NH₃.

According to the preferred embodiment of the present invention, the blocking layer structure may be formed based on MOCVD technology, and the materials for growing the blocking layer structure may include group III including at least one of TMIn, TMGa, TEGa, and group V including at least one of PH₃, TBP, AsH₃, TESb, NH₃ and TBAs.

The accompanying drawings are included to provide a further understanding of the invention, and are incorporated in and constitute a part of this specification. The drawings illustrate the preferred embodiments of the present invention and, together with the description, serve to explain the principles of the present invention.

As shown in FIG. 1, FIG. 1 is a sectional view illustrating a HBT according to a first preferred embodiment of the present invention.

According to the first embodiment of the present invention, as shown in FIG. 1, the HBT of the present invention includes a substrate 10 formed by GaAs; a subcollector layer 20 stacked on the substrate 10, wherein a part of or all of the subcollector layer may be formed by N-type group III-V semiconductors doped by at least Te and/or Se; a blocking layer structure 30 directly or indirectly stacked on the subcollector layer 20, and formed by N-type group semiconductors doped by at least group IV elements, wherein a total group IV elements dosage in the blocking layer structure 30 may be provided, that is, a thickness T of a blocking layer or the sum of thickness T of blocking layers that is multiplied by a group IV elements dosage concentration D of the blocking layer(s) is greater than or equal to 1×10¹² cm⁻² (i.e., ΣT×D≧1×10¹²cm⁻²); a collector layer 40 stacked on the blocking layer structure 30, and formed by N-type group III-V semiconductors; a base layer 50 stacked on the collector layer 40, and formed by P-type group III-V semiconductors; an emitter layer 60 stacked on the base layer 50, and formed by N-type group III-V semiconductors that are different from those of the base layer 50; an emitter cap layer 70 stacked on the emitter layer 60, and formed by N-type group III-V semiconductors; and an ohmic contact layer 80 stacked on the emitter cap layer 70, and formed by N-type group III-V semiconductors.

Besides, as shown in FIG. 1, the blocking layer structure 30 may be formed by a single blocking layer.

As shown in FIG. 1, the blocking layer structure 30 may be formed by one of GaAs, AlGaAs, InGaAs, InGaP, InGaAsP, GaAsSb, InGaAsN, AlAs and AlGaInP.

As shown in FIG. 1, the group IV elements dosage of the blocking layer structure 30 may be formed by at least one of Si, Ge and Sn.

Furthermore, the blocking layer structure 30 of the present invention may be formed based on MOCVD technology, and the materials for growing the blocking layer structure 30 may include group III including at least one of TMAl, TEAl, TMIn, TEIn, TIPIn, TMGa, TEGa, TIPGa, TIBGa and TTBGa and group V including at least one of PH₃, TBP, AsH₃, DMAs, TMAs, TEAs, DEAs, TBAs, TESb, TMSb, DMHy, MMHy and NH₃.

As shown in FIG. 1, the collector layer 40 of the present invention may be formed by at least one of N-type GaAs, AlGaAs, InGaAs, InGaP and InGaAsP. The base layer 50 may be formed by at least one of P-type GaAs, InGaAs, InGaAsN and GaAsSb. The emitter layer 60 may be formed by at least one of N-type AlGaInP, InGaP, InGaAsP and AlGaAs.

As shown in FIG. 1, the emitter cap layer 70 of the present invention may be formed by at least one of N-type GaAs, InGaP, InGaAsP and AlGaAs. In addition, the ohmic contact layer 80 may be formed by at least one of N type GaAs and InGaAs.

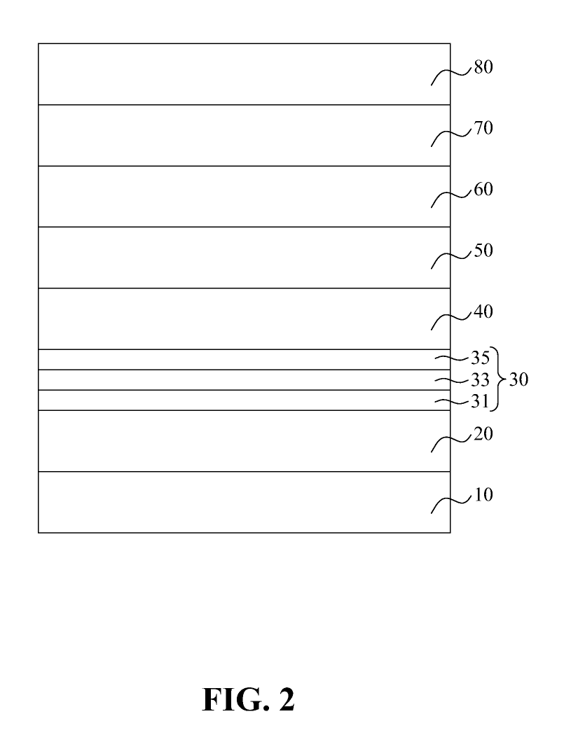

As shown in FIG. 2, FIG. 2 is a sectional view illustrating a HBT according to a second preferred embodiment of the present invention.

According to the second embodiment of the present invention, as shown in FIG. 2, the HBT of the present invention includes a substrate 10 formed by GaAs; a subcollector layer 20 stacked on the substrate 10, wherein a part of or all of the subcollector layer may be formed by N-type group III-V semiconductors doped by at least Te and/or Se; a blocking layer structure 30 directly or indirectly stacked on the subcollector layer 20, and formed by N-type group III-V semiconductors doped by at least group IV elements, wherein a total group IV elements dosage of the blocking layer structure 30 may be provided, that is, a thickness T of a blocking layer or the sum of thickness T of blocking layers that is multiplied by a group IV elements dosage concentration D of the blocking layer(s) is greater than or equal to 1×10¹² cm ⁻² (i.e., T×D≧1×10¹²cm⁻²); a collector layer 40 stacked on the blocking layer structure 30, and formed by N-type group III-V semiconductors; a base layer 50 stacked on the collector layer 40, and formed by P-type group III-V semiconductors; an emitter layer 60 stacked on the base layer 50, and formed by N-type group III-V semiconductors that are different from those of the base layer 50; an emitter cap layer 70 stacked on the emitter layer 60, and formed by N-type group III-V semiconductors; and an ohmic contact layer 80 stacked on the emitter cap layer 70, and formed by N-type group III-V semiconductors.

Besides, as shown in FIG. 2, the blocking layer structure 30 may be formed by a plurality blocking layers 31, 33, and 35.

As shown in FIG. 2, the blocking layer structure 30 may be formed by at least one of GaAs, AlGaAs, InGaAs, InGaP, InGaAsP, GaAsSb, InGaAsN, AlAs, AlGaInP and a combination thereof and/or a superlattice structure.

As shown in FIG. 2, the group IV elements dosage of the blocking layer structure 30 may be formed by at least one of Si, Ge and Sn.

Furthermore, the blocking layer structure 30 of the present invention may be formed based on MOCVD technology, and the materials for growing the blocking layer structure 30 may include group III including at least one of TMAl, TEAl, TMIn, TEIn, TIPIn, TMGa, TEGa, TIPGa, TIBGa and TTBGa and group V including at least one of PH₃, TBP, AsH₃, DMAs, TMAs, TEAs, DEAs, TBAs, TESb, TMSb, DMHy, MMHy and NH₃.

As shown in FIG. 2, the collector layer 40 of the present invention may be formed by at least one of N-type GaAs, AlGaAs, InGaAs, InGaP and InGaAsP. The base layer 50 may be formed by at least one of P-type GaAs, InGaAs, InGaAsN and GaAsSb. The emitter layer 60 may be formed by at least one of N-type AlGaInP, InGaP, InGaAsP and AlGaAs.

As shown in FIG. 2, the emitter cap layer 70 of the present invention may be formed by at least one of N-type GaAs, InGaP, InGaAsP and AlGaAs. In addition, the ohmic contact layer 80 may be formed by at least one of N-type GaAs and InGaAs.

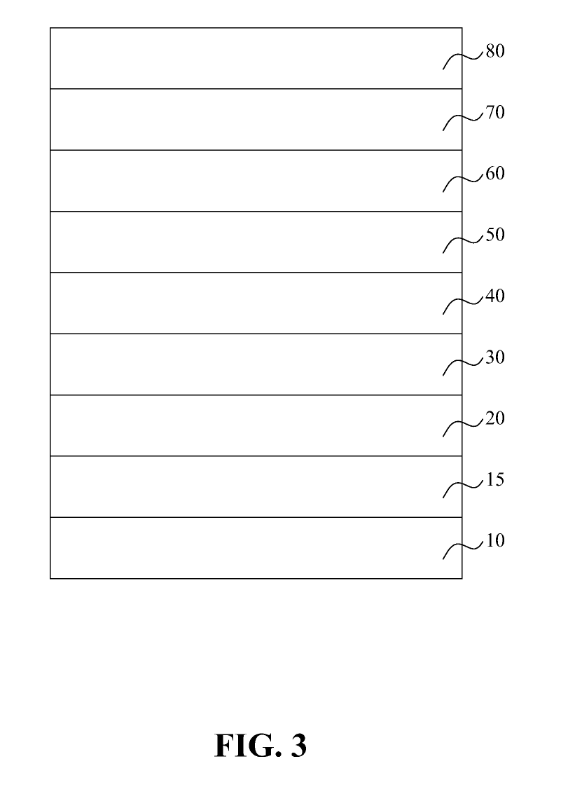

As shown in FIG. 3, FIG. 3 is a sectional view illustrating a HBT according to a third preferred embodiment of the present invention.

According to the third embodiment of the present invention, a HBT of the present invention may include a substrate 10 formed by GaAs; a transistor 15 directly or indirectly stacked on the substrate 10; a subcollector layer 20 stacked on the transistor 15, wherein a part of or all of the subcollector layer may be formed by N-type group III-V semiconductors doped by at least Te and/or Se; a blocking layer structure 30 directly or indirectly stacked on the subcollector layer 20, and formed by N-type group III-V semiconductors doped by at least group IV elements, wherein a total group IV elements dosage of the blocking layer structure 30 may be provided, that is, a thickness T of a blocking layer or the sum of thicknesses T of blocking layers that is multiplied by a group IV elements dosage concentration D of the blocking layer(s) is greater than or equal to 1×10¹² cm⁻²; a collector layer 40 stacked on the blocking layer structure 30, and formed by N-type group III-V semiconductors; a base layer 50 stacked on the collector layer 40, and formed by P-type group III-V semiconductors; an emitter layer 60 stacked on the base layer 50, and formed by N-type group III-V semiconductors that are different from those of the base layer 50; an emitter cap layer 70 stacked on the emitter layer 60, and formed by N-type group III-V semiconductors; and an ohmic contact layer 80 stacked on the emitter cap layer 70, and formed by N-type group III-V semiconductor.

The transistor 15 of the present invention may be a Field-effect Transistor (FET), according to the third preferred embodiment of the present invention.

Besides, as shown in FIG. 3, the blocking layer structure 30 may be formed by a single blocking layer.

As shown in FIG. 3, the blocking layer structure 30 may be formed by one of GaAs, AlGaAs, InGaAs, InGaP, InGaAsP, GaAsSb, InGaAsN, AlAs and AlGaInP.

As shown in FIG. 3, the group IV elements dosage of the blocking layer structure 30 may be formed by at least one of Si, Ge and Sn.

Furthermore, the blocking layer structure 30 of the present invention may be formed based on MOCVD technology, and the materials for growing the blocking layer structure 30 may include group III including at least one of TMAl, TEAl, TMIn, TEIn, TIPIn, TMGa, TEGa, TIPGa, TIBGa and TTBGa and group V including at least one of PH₃, TBP, AsH₃, DMAs, TMAs, TEAs, DEAs, TBAs, TESb, TMSb, DMHy, MMHy and NH₃.

As shown in FIG. 3, the collector layer 40 may be formed by at least one of N-type GaAs, AlGaAs, InGaAs, InGaP and InGaAsP. The base layer 50 may be formed by at least one of P-type GaAs, InGaAs, InGaAsN and GaAsSb. The emitter layer 60 may be formed by at least one of N-type AlGaInP, InGaP, InGaAsP and AlGaAs.

The emitter cap layer 70 may be formed by at least one of N-type GaAs, InGaP, InGaAsP and AlGaAs. Additionally, the ohmic contact layer 80 may be formed by at least one of N-type GaAs and InGaAs.

Furthermore, if the transistor 15 of the present invention is a pHEMT, the pHEMT may include at least one buffer layer, a first donor layer, a first spacer layer, a channel layer, a second spacer layer, a second donor layer, a Schottky layer, an etch stop layer, and a cap layer for ohmic contact that are sequentially formed on the substrate from bottom to top, wherein the at least one buffer layer may be formed by group III-V semiconductors. The first donor layer and the second donor layer may be formed by at least one of N-type GaAs, N-type AlGaAs, N-type InAlGaP, N-type InGaP and N-type InGaAsP. The first spacer layer and the second spacer layer may be formed by at least one of GaAs, AlGaAs, InAlGaP, InGaP and InGaAsP. The channel layer may be formed by at least one of GaAs, InGaAs, AlGaAs, InAlGaP, InGaP and InGaAsP. The Schottky layer may be formed by at least one of GaAs, AlGaAs, InAlGaP, InGaP and InGaAsP. The etch stop layer may be formed by at least one of GaAs, AlGaAs, InAlGaP, InGaAsP, InGaP and AlAs. Additionally, the cap layer may be formed by N-type group III-V semiconductors.

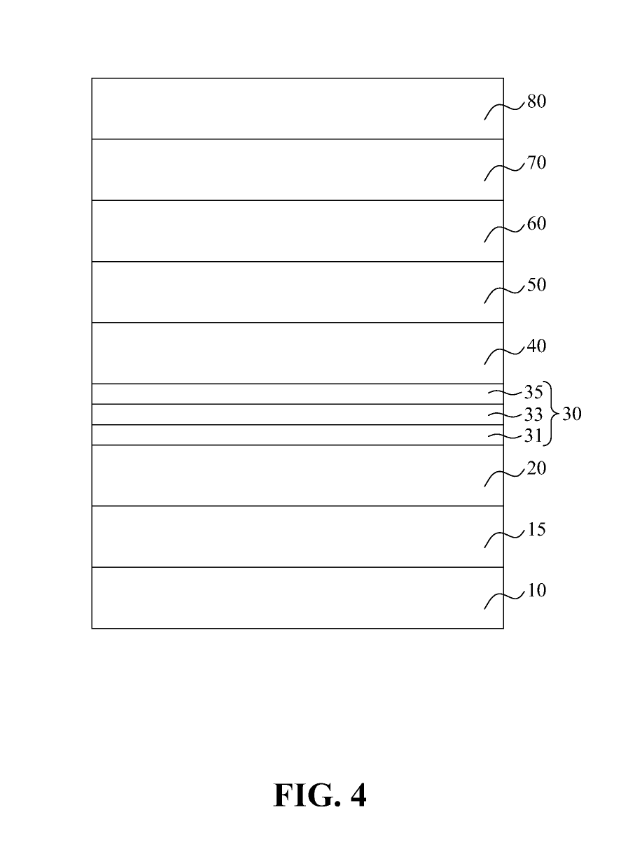

As shown in FIG. 4, FIG. 4 is a sectional view illustrating a HBT according to a fourth preferred embodiment of the present invention.

According to the fourth embodiment of the present invention, a HBT of the present invention includes a substrate 10 formed by GaAs; a transistor 15 directly or indirectly stacked on the substrate 10; a subcollector layer 20 stacked on the transistor 15, wherein a part of or all of the subcollector layer may be formed by N-type group III-V semiconductors doped by at least Te and/or Se; a blocking layer structure 30 directly or indirectly stacked on the subcollector layer 20, and formed by N-type group III-V semiconductors doped by at least group IV elements, wherein a total group IV elements dosage in the blocking layer structure 30 may be provided, that is, a thickness T of a blocking layer or the sum of thicknesses T of blocking layers that is multiplied by a group IV elements dosage concentration D of the blocking layer(s) is greater than or equal to 1×10¹² cm⁻²; a collector layer 40 stacked on the blocking layer structure 30, and formed by N-type group III-V semiconductors; a base layer 50 stacked on the collector layer 40, and formed by P-type group III-V semiconductors; an emitter layer 60 stacked on the base layer 50, and formed by N-type group III-V semiconductors that are different from those of the base layer 50; an emitter cap layer 70 stacked on the emitter layer 60, and formed by N-type group III-V semiconductors; and an ohmic contact layer 80 stacked on the emitter cap layer 70, and formed by N-type group III-V semiconductors.

The transistor 15 of the present invention may be a field-effect transistor (FET), according to the fourth preferred embodiment of the present invention.

Besides, as shown in FIG. 4, the blocking layer structure 30 may be formed by a plurality blocking layers 31, 33, 35.

As shown in FIG. 4, the blocking layer structure 30 may be formed by at least one of GaAs, AlGaAs, InGaAs, InGaP, InGaAsP, GaAsSb, InGaAsN, AlAs, AlGaInP and a combination thereof and/or a superlattice structure.

As shown in FIG. 4, the group IV elements dosage of the blocking layer structure 30 may be formed by at least one of Si, Ge and Sn.

Furthermore, the blocking layer structure 30 of the present invention may be formed based on MOCVD technology, and the materials for growing the blocking layer structure 30 may include group III including at least one of TMAl, TEAl, TMIn, TEIn, TIPIn, TMGa, TEGa, TIPGa, TIBGa and TTBGa and group V including at least one of PH₃, TBP, AsH₃, DMAs, TMAs, TEAs, DEAs, TBAs, TESb, TMSb, DMHy, MMHy and NH₃.

As shown in FIG. 4, the collector layer 40 may be formed by at least one of N-type GaAs, AlGaAs, InGaAs, InGaP and InGaAsP. The base layer 50 may be formed by at least one of P-type GaAs, InGaAs, InGaAsN and GaAsSb. The emitter layer 60 may be formed by at least one of N-type AlGaInP, InGaP, InGaAsP and AlGaAs. The emitter cap layer 70 may be formed by at least one of N-type GaAs, InGaP, InGaAsP and AlGaAs. The ohmic contact layer 80 may be formed by at least one of N type GaAs and InGaAs.

Furthermore, if the transistor 15 of the present invention is a pHEMT, the pHEMT includes at least one buffer layer, a first donor layer, a first spacer layer, a channel layer, a second spacer layer, a second donor layer, a Schottky layer, an etch stop layer, and a cap layer for an ohmic contact that are sequentially formed on the substrate from bottom to top. The at least one buffer layer may be formed by group III-V semiconductors. The first donor layer and the second donor layer may be formed by at least one of N-type GaAs, N-type AlGaAs, N-type InAlGaP, N-type InGaP and N-type InGaAsP. The first spacer layer and the second spacer layer may be formed by at least one of GaAs, AlGaAs, InAlGaP, InGaP and InGaAsP. The channel layer may be formed by at least one of GaAs, InGaAs, AlGaAs, InAlGaP, InGaP and InGaAsP. The Schottky layer may be formed by at least one of GaAs, AlGaAs, InAlGaP, InGaP and InGaAsP. The etch stop layer may be formed by at least one of GaAs, AlGaAs, InAlGaP, InGaAsP, InGaP and AlAs. Moreover, the cap layer may be formed by N type group III-V semiconductors.

According to the present invention, as compared with the prior art, the present invention not only effectively reduces knee voltage of the HBT, but also achieves the CV profile of the base-collector junction that is designed initially so as to obtain lower sheet resistance of the subcollector layer. Therefore, the present invention can really solve the problems of the prior art, and improve the overall electrical characteristic of the HBT.

The above exemplary embodiment describes the principle and effect of the present invention, but is not limited to the present invention. It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A heterojunction bipolar transistor (HBT), comprising:
a substrate formed by GaAs;
a subcollector layer stacked on the substrate, wherein a part of or all of the subcollector layer is formed by N-type group III-V semiconductors doped by at least Te and/or Se;
a blocking layer structure directly or indirectly stacked on the subcollector layer, and formed by N-type group III-V semiconductors doped by at least group IV elements, wherein a total group IV elements dosage of the blocking layer structure is provided since a thickness T of a blocking layer or the sum of thicknesses T of blocking layers that is multiplied by a group IV elements dosage concentration D of the blocking layer(s) is greater than or equal to 1×10¹² cm⁻² (ΣT×D≧1×10¹² cm⁻²);
a collector layer stacked on the blocking layer structure, and formed by N-type group III-V semiconductors;
a base layer stacked on the collector layer, and formed by P-type group III-V semiconductors;
an emitter layer stacked on the base layer, and formed by N-type group III-V semiconductors that are different from the group III-V semiconductors of the base layer;
an emitter cap layer stacked on the emitter layer, and formed by N-type group III-V semiconductors; and
an ohmic contact layer stacked on the emitter cap layer, and formed by N-type group III-V semiconductors.

2. The HBT as claimed in claim 1, wherein the blocking layer structure is formed by a single blocking layer or a plurality of blocking layers.

3. The HBT as claimed in claim 1, wherein at least one layer of the blocking layer structure comprises the group IV elements dosage concentration greater than or equal to 1×10¹⁸ cm⁻³.

4. The HBT as claimed in claim 1, wherein the blocking layer structure is formed by at least one of GaAs, AlGaAs, InGaAs, InGaP, InGaAsP, GaAsSb, InGaAsN, AlAs, AlGaInP and a combination thereof and/or a superlattice structure.

5. The HBT as claimed in claim 1, wherein the group IV elements dosage of the blocking layer structure is formed by at least one of Si, Ge and Sn.

6. The HBT as claimed in claim 1, wherein the blocking layer structure directly stacked on the subcollector layer is formed by at least one of GaAs, AlGaAs, InGaAs, InGaP, InGaAsP, GaAsSb, InGaAsN, AlAs, AlGaInP and a combination thereof and/or a superlattice structure.

7. The HBT as claimed in claim 6, wherein the group IV elements dosage of the blocking layer structure is formed by at least one of Si, Ge and Sn.

8. The HBT as claimed in claim 1, wherein the blocking layer structure is formed based on MOCVD technology, and materials for growing the blocking layer structure comprise group III including at least one of TMAl, TEAl, TMIn, TEIn, TIPIn, TMGa, TEGa, TIPGa, TIBGa and TTBGa and group V including at least one of PH₃, TBP, AsH₃, DMAs, TMAs, TEAs, DEAs, TBAs, TESb, TMSb, DMHy, MMHy and NH₃.

9. The HBT as claimed in claim 1, wherein the collector layer is formed by at least one of N-type GaAs, AlGaAs, InGaAs, InGaP and InGaAsP, wherein the base layer is formed by at least one of P-type GaAs, InGaAs, InGaAsN and GaAsSb, wherein the emitter layer is formed by at least one of N-type AlGaInP, InGaP, InGaAsP and AlGaAs, wherein the emitter cap layer is formed by at least one of N-type GaAs, InGaP, InGaAsP and AlGaAs, and wherein the ohmic contact layer is formed by at least one of N-type GaAs and InGaAs.

10. A heterojunction bipolar transistor (HBT), comprising:
a substrate formed by GaAs;
a transistor directly or indirectly stacked on the substrate;
a subcollector layer stacked on the transistor, wherein a part of or all of the subcollector layer is formed by N-type group III-V semiconductors doped by at least Te and/or Se;
a blocking layer structure directly or indirectly stacked on the subcollector layer, and formed by N-type group III-V semiconductors doped by at least group IV elements, wherein a total group IV elements dosage of the blocking layer structure is provided since a thickness T of a blocking layer or the sum of thicknesses T of blocking layers that is multiplied by a group IV elements dosage concentration D of the blocking layer(s) is greater than or equal to 1×10¹² cm⁻² (ΣT×D≧1×10¹² cm⁻²);
a collector layer stacked on the blocking layer structure, and formed by N-type group III-V semiconductors;
a base layer stacked on the collector layer, and formed by P-type group III-V semiconductors;
an emitter layer stacked on the base layer, and formed by N-type group III-V semiconductors that are different from the group III-V semiconductors of the base layer;
an emitter cap layer stacked on the emitter layer, and formed by N-type group III-V semiconductors; and
an ohmic contact layer stacked on the emitter cap layer, and formed by N-type group III-V semiconductors.

11. The HBT as claimed in claim 10, wherein the transistor is a Field-effect transistor (FET).

12. The HBT as claimed in claim 10, wherein the blocking layer structure is formed by a single blocking layer or a plurality of blocking layers.

13. The HBT as claimed in claim 10, wherein at least one layer of the blocking layer structure comprises the group IV elements dosage concentration greater than or equal to 1×10¹⁸ cm⁻³.

14. The HBT as claimed in claim 10, wherein the blocking layer structure is formed by at least one of GaAs, AlGaAs, InGaAs, InGaP, InGaAsP, GaAsSb, InGaAsN, AlAs, AlGaInP and a combination thereof and/or a superlattice structure.

15. The HBT as claimed in claim 10, wherein the group IV elements dosage of the blocking layer structure is formed by at least one of Si, Ge and Sn.

16. The HBT as claimed in claim 10, wherein the blocking layer structure directly stacked on the subcollector layer is formed by at least one of GaAs, AlGaAs, InGaAs, InGaP, InGaAsP, GaAsSb, InGaAsN, AlAs, AlGaInP and a combination thereof and/or a superlattice structure.

17. The HBT as claimed in claim 16, wherein the group IV elements dosage of the blocking layer structure is formed by at least one of Si, Ge and Sn.

18. The HBT as claimed in claim 10, wherein the blocking layer structure is formed based on MOCVD technology, and materials for growing the blocking layer structure comprise group III including at least one of TMAl, TEAl, TMIn, TEIn, TIPIn, TMGa, TEGa, TIPGa, TIBGa and TTBGa, and group V including at least one of PH₃, TBP, AsH₃, DMAs, TMAs, TEAs, DEAs, TBAs, TESb, TMSb, DMHy, MMHy and NH₃.

19. The HBT as claimed in claim 10, wherein the collector layer is formed by at least one of N-type GaAs, AlGaAs, InGaAs, InGaP and InGaAsP, wherein the base layer is formed by at least one of P-type GaAs, InGaAs, InGaAsN and GaAsSb, wherein the emitter layer is formed by at least one of N-type AlGaInP, InGaP, InGaAsP and AlGaAs, wherein the emitter cap layer is formed by at least one of N-type GaAs, InGaP, InGaAsP and AlGaAs, and wherein the ohmic contact layer is formed by at least one of N-type GaAs and InGaAs.

20. The HBT as claimed in claim 10, wherein the FET is a pHEMT includes at least one buffer layer, a first donor layer, a first spacer layer, a channel layer, a second spacer layer, a second donor layer, a Schottky layer, an etch stop layer, and a cap layer for an ohmic contact that are sequentially formed on the substrate from bottom to top, wherein the at least one buffer layer is formed by group III-V semiconductors, the first donor layer and the second donor layer are formed by at least one of N-type GaAs, N-type AlGaAs, N-type InAlGaP, N-type InGaP and N-type InGaAsP, the first spacer layer and the second spacer layer are formed by at least one of GaAs, AlGaAs, InAlGaP, InGaP and InGaAsP, the channel layer is formed by at least one of GaAs, InGaAs, AlGaAs, InAlGaP, InGaP and InGaAsP, the Schottky layer is formed by at least one of GaAs, AlGaAs, InAlGaP, InGaP and InGaAsP, the etch stop layer is formed by at least one of GaAs, AlGaAs, InAlGaP, InGaAsP, InGaP and AlAs, and the cap layer is formed by N-type group III-V semiconductors.
